(19) United States
(12) Patent Application Publication
(10) Pub. No.: US 2018/0148857 A1
(43) Pub. Date: May 31, 2018

(54) METHOD FOR REGENERATING MEMBER WITHIN SILICON SINGLE CRYSTAL PULLING APPARATUS

(71) Applicant: SUMCO CORPORATION, Tokyo (JP)

(72) Inventor: Toshiro KOTOOKA, Yamagata (JP)

(73) Assignee: SUMCO CORPORATION, Tokyo (JP)

(21) Appl. No.: 15/570,533

(22) PCT Filed: May 11, 2016
(86) PCT No.: PCT/JP2016/063972

§ 371 Date: Oct. 30, 2017

(30) Foreign Application Priority Data
Jul. 2, 2015 (JP) 2015-133184

(51) Int. Cl. C30B 15/14; C30B 29/06; C30B 15/10; C30B 15/20

(52) U.S. Cl. CPC C30B 15/14; C30B 15/20; C30B 15/10; C30B 29/06

(57) ABSTRACT

In a regeneration method of the present invention, a member, to the surface of which silicon or the like adheres, is subjected to a heat treatment for at least two hours in an inert gas atmosphere at a pressure of 2.67 kPa or less so that the surface of the member is at a temperature at which SiOx and/or silicon metal adhering to the surface starts to sublimate or higher but less than a temperature at which the member starts thermal deformation and/or thermal alteration, thereby removing silicon or the like adhering to the surface of the member by means of sublimation.

### TECHNICAL FIELD

The present invention relates to a method for regenerating a member provided in a silicon single crystal pulling apparatus by removing any one of SiOx and silicon metal or both from the member with the surface to which any one of SiOx and silicon metal or both adheres. This international application is based upon and claims the benefit of priority from Japanese Patent Application No. 133184 (2015-133184), filed Jul. 2, 2015, the entire contents of which are incorporated herein by reference.

### BACKGROUND ART

Conventionally, in an apparatus that pulls a silicon single crystal upwardly by the Czochralski process, any one of SiOx, such as SiO or SiO₂, and silicon metal or both (hereinafter simply referred to as “silicon or the like”) have evaporated from the surface of silicon melt, and the silicon or the like has adhered to the surfaces of various members such as a thermal shielding member and a flow regulating tube which are provided in the pulling apparatus and gradually solidified. The silicon or the like adhering thereto and solidified sometimes falls off the surface of the member due to a change in the velocity of flow of an inert gas that flows in the pulling apparatus or a change in the thermal expansion of the member to which the silicon or the like adheres and falls into the silicon melt. The silicon or the like that has fallen thereinto becomes impurities in the silicon melt and becomes a factor that inhibits crystallization of a silicon single crystal to be pulled upwardly. If the flow regulating tube provided in the pulling apparatus is made of quartz, the silicon or the like adheres to the surface of quartz of the flow regulating tube and gradually changes to brown. When observation of the inside of a furnace is carried out through the flow regulating tube made of quartz, the adhesion of the silicon or the like makes it impossible to carry out the observation of the inside of the furnace.

To solve this problem, the members such as the thermal shielding member and the flow regulating tube were cleaned with a brush to remove the silicon or the like adhering to the surfaces of the members, but it was impossible to remove the silicon or the like completely. For this reason, a method for regenerating a thermal shielding member of a silicon single crystal pulling apparatus is disclosed (refer to, for example, Patent Document 1). In this method silicon or the like adheres to the thermal shielding member being a graphite member is removed by chemical cleaning the thermal shielding member outside a silicon single crystal pulling apparatus by performing this regeneration in appropriate cycles so as to suppress the quality variation of silicon single crystal ingots. In this regeneration method, the thermal shielding member to which the silicon or the like adheres during pulling is taken out of the silicon single crystal pulling apparatus and SiOx adherents are removed by cleaning in a chemical solution tank in which a mixed acid of hydrofluoric acid and nitric acid is stored and a rinse tank in which pure water is stored, whereby the thermal shielding member is regenerated.

On the other hand, a method for regenerating a SiC-coated graphite member that is used in a member for pulling a single crystal upwardly, a susceptor for epitaxial growth of a Si wafer, or the like, in a semiconductor production process and reaches the end of the life thereof, the method that can uniformly remove SiC with which the surface is coated, is disclosed (refer to, for example, Patent Document 2). In this regeneration method, after SiC with which the surface of a base material of a SiC-coated graphite member is coated is removed by subliming SiC by performing heat treatment at 1700° C. or higher at a pressure of 1.33 kPa or less, or in an inert gas atmosphere, or in an inert gas atmosphere at a pressure of 1.33 kPa or less, the base material is coated with SiC by CVD and is reused as a SiC-coated graphite member. In addition, Patent Document 2 describes that, if silicon metal adheres to the surface of SiC of the susceptor for epitaxial growth used in the semiconductor production process, the silicon metal may be removed along with SiC at the time of the above-described heat treatment or, before the above-described heat treatment, the silicon metal may be dissolved in a hydrofluoric-nitric acid solution or mechanically removed by a grinding wheel.

Patent Document 1: JP-A-2001-010895 (Abstract, FIG. 1)

Patent Document 2: JP-A-2002-037684 (Abstract, paragraph [0009])

### DISCLOSURE OF INVENTION

### Problem to be Solved by the Invention

However, if a thermal shielding member which is a graphite member is regenerated by an etching processing method by chemical cleaning of Patent Document 1, it takes four to five days to perform cleaning by a chemical solution, four to five days to perform cleaning by pure water, and four to five days to perform drying, which means that about two weeks are required to complete the regeneration processing and makes it impossible to regenerate efficiently a thermal shielding member to which silicon or the like adheres. Moreover, with this etching regeneration method, it is difficult to remove the silicon or the like completely, and, in addition thereto, when regeneration is performed about 70 times, reuse as a thermal shielding member becomes impossible. Furthermore, if a flow regulating tube which is a quartz member is regenerated by the etching processing method by chemical cleaning of Patent Document 1, the shortest possible cycle time required to perform cleaning by a chemical solution, cleaning by pure water, drying, and then baking is two to three days, which makes it impossible to regenerate efficiently a thermal shielding member to which silicon or the like adheres. Moreover, if a flow regulating tube is regenerated by etching, since the wall thickness of the flow regulating tube is reduced by etching, a reduction in wall thickness makes it impossible for the flow regulating tube to satisfy a predetermined thickness when regeneration is performed about 100 times and the flow regulating tube reaches the end of the life thereof.

Furthermore, if the thermal shielding member is a member formed of a graphite base material whose surface is coated with SiC, the chemical solution penetrates between the graphite base material and the SiC coating in this etching regeneration method, which undesirably causes the SiC coating to peel off. In addition, if the graphite member is a carbon fiber reinforced composite material (hereinafter referred to as the “CC composite material”) formed of woven carbon fibers, there is a possibility that the chemical solution is absorbed between the carbon fibers at the time of cleaning by the chemical solution, which results in a prolonged time required for drying and causes the chemical solution to remain between the carbon fibers.

In the method for regenerating a SiC-coated graphite member of Patent Document 2, when silicon metal adheres to the surface of SiC and is removed along with SiC at the time of heat treatment, the surface of the base material has to be recoated with SiC, whereby it takes a long time to perform regeneration. Moreover, when the silicon metal is dissolved in a hydrofluoric-nitric acid solution before the heat treatment, a problem similar to that of the regeneration method of Patent Document 1 arises. Furthermore, when the silicon metal is mechanically removed by a grinding wheel, there is a possibility that the wall thickness of the SiC-coated graphite member is reduced or the surface of the member is damaged.

A first object of the present invention is to provide a method for regenerating a member in a silicon single crystal pulling apparatus by removing silicon or the like by completely subliming the silicon or the like, the method that solves the above-described problems, can be applied to all the members, to which silicon or the like adheres, in the silicon single crystal pulling apparatus, shortens the time required for regeneration, does not reduce the wall thickness of the member, and is free from risk of degrading or damaging the surface of the member. A second object of the present invention is to provide a method for regenerating a member in a silicon single crystal pulling apparatus, the method that greatly prolongs the usable period of the member in the silicon single crystal pulling apparatus, increases the single crystallization degree of a silicon single crystal to be pulled upwardly, and maintains or improves the quality of the lifetime of this single crystal.

### Means for Solving Problem

According to a first aspect of the present invention, in a method that regenerates a member which is provided in a silicon single crystal pulling apparatus by removing any one of SiOx and silicon metal or both (silicon or the like) adhering to the surface of the member, the one of SiOx and silicon metal or both adhering to the surface of the member is removed by subliming the one of SiOx and silicon metal or both by performing heat treatment, for at least two hours, on the member with the surface to which the silicon or the like adheres in an inert gas atmosphere at a pressure of 2.67 kPa or less at a temperature, at which the surface temperature of the member is higher than or equal to a temperature at which sublimation of the one of SiOx and silicon metal or both adhering to the surface starts, which is lower than a temperature at which the member starts any one of thermal deformation and thermal alteration or both.

According to a second aspect of the present invention, in the invention according to the first aspect, after the heat treatment is performed, the member is cooled from the heat treatment temperature to room temperature at a rate of 3 to 15° C./minute.

According to a third aspect of the present invention, in the invention according to the first or second aspect, the member is a graphite member and the heat treatment temperature is at least 1700° C. or more.

According to a fourth aspect of the present invention, in the invention according to the third aspect, the graphite member is a graphite member coated with SiC and the heat treatment temperature is 1700° C. or higher but 2500° C. or lower.

According to a fifth aspect of the present invention, in the invention according to the third aspect, the graphite member is a graphite member coated with a carbon film and the heat treatment temperature is 1700° C. or higher but 2500° C. or lower.

According to a sixth aspect of the present invention, in the invention according to any one of the third to fifth aspects, the graphite member is a thermal shielding member.

According to a seventh aspect of the present invention, in the invention according to the first or second aspect, the member is a quartz member and the heat treatment temperature is 1400° C. or higher but 1700° C. or lower.

According to an eighth aspect of the present invention, in the invention according to the seventh aspect, the quartz member is a flow regulating tube.

A ninth aspect of the present invention is directed to a member that is provided in a silicon single crystal pulling apparatus, the member regenerated by the method according to any one of the first to eighth aspects.

A tenth aspect of the present invention is directed to a method for producing a silicon single crystal by using a member regenerated by the method according to any one of the first to eighth aspects.

### Effect of the Invention

In the regeneration method of the first aspect of the present invention, unlike the regeneration method of Patent Document 1, since silicon or the like is removed by completely subliming the silicon or the like by heat treatment without using a chemical solution, the regeneration method of the first aspect of the present invention can be applied to all the members, to which silicon or the like adheres, in the silicon single crystal pulling apparatus. Moreover, unlike the regeneration methods of Patent Documents 1 and 2, since a chemical solution is not used and SiC coating by second CVD is not performed, the time required for regeneration can be shortened. Furthermore, unlike the regeneration method of Patent Document 1 or 2, since silicon or the like is not removed by use of a chemical solution or a grinding wheel, the wall thickness of a member is not reduced and there is no possibility that the surface of the member is degraded or damaged. In addition, it is possible to greatly prolong the usable period of the member in the silicon single crystal pulling apparatus, increase the single crystallization degree of a silicon single crystal to be pulled upwardly, and maintain or improve the quality of the lifetime of this single crystal.

In the regeneration method of the second aspect of the present invention, by rapidly cooling the member from the heat treatment temperature to room temperature at a rate of 3 to 15° C./minute after the heat treatment is performed, it is possible to remove the silicon or the like by making the silicon or the like easily fall off the member by using a difference in coefficient of thermal expansion between the member and the silicon or the like.

In the regeneration method of the third aspect of the present invention, when the member is a graphite member, by setting the regeneration heat treatment temperature at at least 1700° C. or more, it is possible to regenerate the graphite member.

In the regeneration method of the fourth aspect of the present invention, when the graphite member is a graphite member coated with SiC, by setting an upper limit of the regeneration heat treatment temperature at 2500° C., it is possible to regenerate the graphite member without allowing SiC with which the graphite member is coated to sublime.

In the regeneration method of the fifth aspect of the present invention, when the graphite member is a graphite member coated with a carbon film, by setting an upper limit of the regeneration heat treatment temperature at 2500° C., it is possible to regenerate the graphite member without allowing the carbon film with which the graphite member is coated to sublime.

In the regeneration method of the sixth aspect of the present invention, since the graphite member is a thermal shielding member to which a relatively large amount of silicon or the like which is matter evaporating from silicon melt adheres, regeneration has beneficial economic effects.

In the regeneration method of the seventh aspect of the present invention, when the member is a quartz member, by setting an upper limit of the regeneration heat treatment temperature at 1700° C., it is possible to regenerate the quartz member without the occurrence of any one of thermal deformation and thermal alteration or both of the quartz member.

In the regeneration method of the eighth aspect of the present invention, since the quartz member is a flow regulating tube to which a relatively large amount of silicon or the like which is matter evaporating from silicon melt adheres, regeneration has beneficial economic effects.

The regenerated member that is provided in the silicon single crystal pulling apparatus of the ninth aspect of the present invention is free from risk of causing the silicon or the like to fall into the silicon melt and can increase the single crystallization degree of a silicon single crystal to be pulled upwardly and maintain or improve the quality of the lifetime of this single crystal.

The method for producing a silicon single crystal by using the regenerated member of the tenth aspect of the present invention can increase the single crystallization degree of a silicon single crystal to be pulled upwardly and maintain or improve the quality of the lifetime of this single crystal.

### BRIEF DESCRIPTION OF DRAWINGS

FIG. 1 is a configuration diagram of an apparatus that regenerates a member according to a first embodiment of the present invention; and

FIG. 2 is a configuration diagram of an apparatus that regenerates a member according to a second embodiment of the present invention.

### BEST MODES FOR CARRYING OUT THE INVENTION

Next, modes for carrying out the present invention will be explained with reference to the drawings.

### First Embodiment

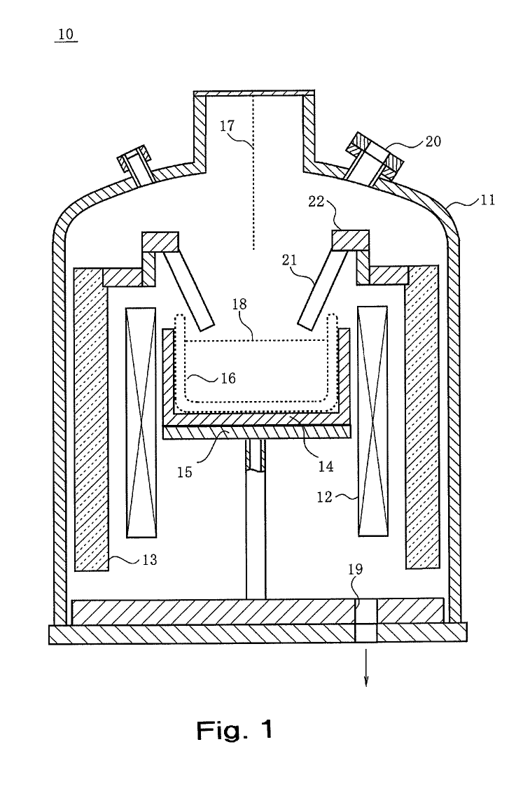

FIG. 1 is a configuration diagram of an apparatus that regenerates a thermal shielding member which is a member in a silicon single crystal pulling apparatus according to a first embodiment of the present invention. This regeneration apparatus uses an apparatus that pulls a silicon single crystal upwardly by the Czochralski process. In this embodiment, a regeneration apparatus 10 includes a chamber 11, a heater 12, a heat insulator 13, a graphite crucible 14, and a crucible holder 15. In this regeneration apparatus 10, since a quartz crucible 16 and a pulling wire 17, which are used when a silicon single crystal is pulled upwardly, are detached, the quartz crucible 16, the pulling wire 17, and silicon melt 18 which is stored in the quartz crucible 16 are each indicated by a dashed line.

The chamber 11 is a container whose diameter is large in an upper part thereof and small in a lower part thereof and is hermetically sealed and isolated from the ambient atmosphere and houses, in the lower part thereof with a large diameter, the heater 12, the heat insulator 13, the graphite crucible 14, the crucible holder 15, and so forth. In the upper part of the chamber 11, an unillustrated inert gas introducing unit through which an inert gas is introduced into the chamber is provided. Moreover, an inert gas exhaust port 19 is provided in the lower part of the chamber 11 and is connected to a vacuum pump via an unillustrated exhaust pipe line. Furthermore, in a shoulder portion of the chamber 11 which is located between the upper part with a small diameter and the lower part with a large diameter, an inspection window 20 is provided. When a silicon single crystal is pulled upwardly, this inspection window 20 is used to measure the diameter of silicon in a silicon single crystal necking process; in this embodiment, the inspection window 20 is used to observe the surface of a thermal shielding member 21 at the time of regeneration heat treatment.

In this embodiment, a member that requires regeneration is the thermal shielding member 21 which is a graphite member. The thermal shielding member 21 is attached to a support member 22 provided in an upper part of the heat insulator 13 in the chamber 11. As the thermal shielding member 21, a member whose base material is made of graphite and whose surface is coated with SiC, a member whose base material is made of graphite and whose surface is coated with a carbon (C) film, or a member whose base material is made of graphite and whose surface is not coated with SiC nor with a carbon (C) film is taken up as an example. The thermal shielding member 21 is provided to suppress radiant heat which a single crystal receives from the silicon melt 18 in the quartz crucible 16 when the silicon single crystal is pulled upwardly, has a tapered shape whose diameter is reduced toward a lower side, and has a lower-end part which extends toward an area near the surface of the silicon melt when the silicon single crystal is pulled upwardly. For this reason, a relatively large amount of silicon or the like which is matter evaporating from the silicon melt 18 adheres to the thermal shielding member 21.

Next, a method for regenerating the thermal shielding member 21 with the silicon or the like adhering thereto and solidified thereon by using the regeneration apparatus 10 will be explained. First, as described above, the thermal shielding member 21 with the silicon or the like adhering thereto and solidified thereon is attached to the support member 22. Then, an inert gas is introduced into the chamber 11 through the unillustrated inert gas introducing unit and the pressure inside the chamber 11 is lowered by operating an unillustrated vacuum pump. The thermal shielding member 21 is heated by the heater 12 in concurrence with the introduction of the inert gas and the reduction in the pressure inside the chamber.

The heat treatment which is performed on the thermal shielding member 21 is conducted in an inert gas atmosphere at a pressure of 2.67 kPa (20 torr) or less and performed for at least two hours at a temperature at which the surface temperature of the thermal shielding member is 1700° C. or higher, the temperature which is lower than a temperature at which the thermal shielding member starts any one of thermal deformation and thermal alteration or both. If the base material of the thermal shielding member 21 is a member made of graphite and whose surface is coated with SiC or the base material is a member made of graphite and whose surface is coated with a carbon (C) film, an upper limit of the surface temperature of the thermal shielding member 21 is set at a temperature lower than or equal to 2500° C. to prevent sublimation of SiC or the carbon film. Sublimation of the silicon or the like starts when the surface temperature of the thermal shielding member 21 becomes 1000° C. or higher; thus, by making settings so that this temperature is 1700° C. or higher, it is possible to remove the silicon or the like completely by making the temperature higher than or equal to the melting point of the silicon or the like. From the viewpoint of saving thermal energy consumption, a desirable temperature is 1700 to 1800° C.

If the surface temperature of the thermal shielding member is lower than 1700° C., sublimation of the silicon or the like adhering to the surface of the thermal shielding member is not easily promoted even in an inert gas atmosphere, which makes it impossible to remove the silicon or the like completely. Moreover, if the thermal shielding member is coated with SiC or coated with a carbon (C) film, when the regeneration processing is performed at a temperature exceeding 2500° C., the film thickness of the SiC coating or the carbon film is reduced due to a sublimation reaction, which undesirably causes the SiC coating or the carbon film to peel off.

Furthermore, the pressure inside the chamber 11 is reduced to 2.67 kPa or less to accelerate sublimation of the silicon or the like adhering to the surface of the thermal shielding member 21 and remove the silicon or the like more uniformly. A desirable pressure is 1.33 kPa (10 torr) or less. At a pressure exceeding 2.67 kPa, sublimation of the silicon or the like adhering to the surface of the thermal shielding member is not easily promoted, which makes it impossible to remove the silicon or the like completely. The time for which, after the surface temperature of the thermal shielding member 21 reaches the above-described temperature, the surface temperature of the thermal shielding member 21 is kept at that temperature is at least two hours. Less than 2 hours makes it difficult to remove the silicon or the like from the thermal shielding member 21 completely. From the viewpoint of saving thermal energy consumption, a desirable time for which the surface temperature was kept at that temperature is 3 to 6 hours. The silicon or the like that has sublimed is exhausted to the outside of the regeneration apparatus 10 from the inert gas exhaust port 19 with the flow of the inert gas introduced through the inert gas introducing unit while the thermal shielding member 21 is subjected to the heat treatment and cooled.

After performing the heat treatment, it is preferable to cool the thermal shielding member 21 from the heat treatment temperature to room temperature at a rate of 3 to 15° C./minute in order to make the silicon or the like easily fall off the thermal shielding member 21 by increasing a difference in coefficient of thermal expansion between the thermal shielding member 21 and the silicon or the like. At a rate less than 3° C./minute, a difference in coefficient of thermal expansion between the thermal shielding member 21 and the silicon or the like is not large and the silicon or the like does not fall off the thermal shielding member 21 easily. Moreover, at a rate exceeding 20° C./minute, there is a possibility that a crack appears in the thermal shielding member. After the thermal shielding member 21 is cooled, the thermal shielding member 21 is taken out of the regeneration apparatus 10, whereby a regenerated thermal shielding member from which the silicon or the like has been completely removed is obtained. In order to achieve more enhancement in the quality of the regenerated thermal shielding member, it is preferable to blow air on the surface of the thermal shielding member with a blower or clean the surface of the thermal shielding member with a brush or cloth.

### Second Embodiment

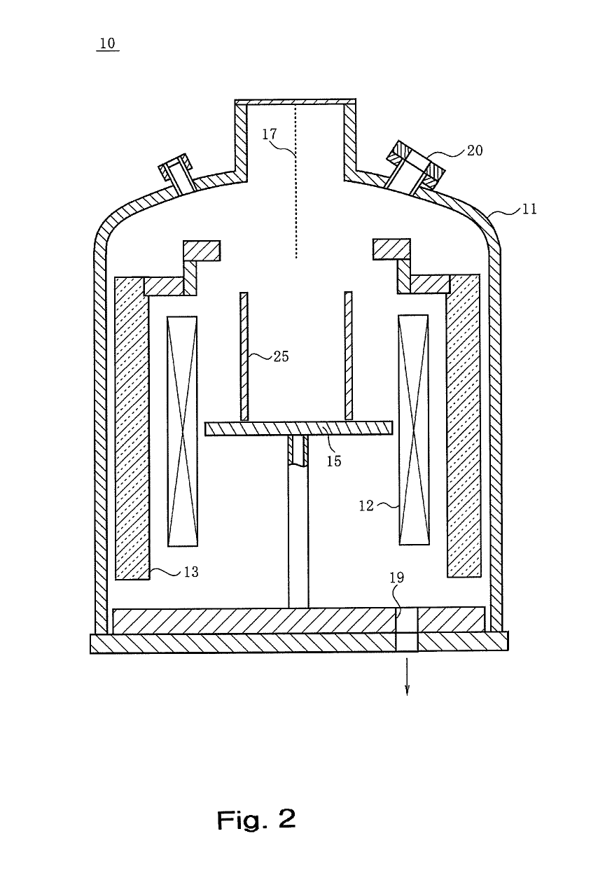

FIG. 2 is a configuration diagram of an apparatus that regenerates a flow regulating tube which is a member in a silicon single crystal pulling apparatus according to a second embodiment of the present invention. As is the case with the first embodiment, this regeneration apparatus uses an apparatus that pulls a silicon single crystal upwardly by the Czochralski process. In FIG. 2, the same numeral as that in FIG. 1 denotes the same element. In this embodiment, a member that requires regeneration is a flow regulating tube 25. As the flow regulating tube 25, a member that is made of quartz, a member that is made of graphite, or a member whose base material is made of graphite and whose surface is coated with SiC or a carbon film is taken up as an example. The flow regulating tube 25 is placed on the flat crucible holder 15 in the regeneration apparatus.

The flow regulating tube 25 is a cylindrical member and is disposed in such a way that, though not depicted in the drawing, the flow regulating tube 25 extends from the small-diameter upper part of the chamber 11 to an area near the surface of the silicon melt when a single crystal is pulled upwardly, so that a single crystal to be pulled upwardly passes through the inside of the flow regulating tube 25. Moreover, the inert gas that is made to flow thereinto through the above-described inert gas introducing unit is led to the surface of the silicon melt 18 through the inside of the flow regulating tube 25. For this reason, a relatively large amount of silicon or the like which is matter evaporating from the silicon melt adheres also to the flow regulating tube 25.

Next, a method for regenerating the flow regulating tube 25 with the silicon or the like adhering thereto and solidified thereon by using the regeneration apparatus 10 will be explained. First, the flow regulating tube 25 with the silicon or the like adhering thereto and solidified thereon is placed on the flat crucible holder 15. Then, the inert gas is introduced into the chamber 11 through the unillustrated inert gas introducing unit and the pressure inside the chamber 11 is lowered by operating the unillustrated vacuum pump. The flow regulating tube 25 is heated by the heater 12 in concurrence with the introduction of the inert gas and the reduction in the pressure inside the chamber.

The heat treatment which is performed on the flow regulating tube 25 is conducted in an inert gas atmosphere at a pressure of 2.67 kPa (20 torr) or less at a temperature of 1400° C. or higher but 2500° C. or lower. If the flow regulating tube 25 is formed of a quartz glass material, an upper limit of the surface temperature of the flow regulating tube 25 is set at a temperature lower than or equal to 1700° C. to prevent heat deformation of the flow regulating tube 25. If the flow regulating tube 25 is made of graphite, an upper limit of the surface temperature of the flow regulating tube 25 is set at a temperature lower than or equal to 2500° C. to protect the surface coating. Sublimation of the silicon or the like starts when the surface temperature of the flow regulating tube 25 becomes 1000° C. or higher; thus, by making settings so that this temperature is 1400° C. or higher, it is possible to remove the silicon or the like completely by making the temperature higher than or equal to the melting point of the silicon or the like. From the viewpoint of saving thermal energy consumption, a desirable temperature is 1700 to 1800° C. Moreover, the pressure inside the chamber 11 is reduced to 2.67 kPa or less to accelerate sublimation of the silicon or the like adhering to the surface of the flow regulating tube 25 and remove the silicon or the like more uniformly. A desirable pressure is 1.33 kPa (10 torr) or less. The time for which, after the surface temperature of the flow regulating tube 25 reaches the above-described temperature, the surface temperature of the flow regulating tube 25 is kept at that temperature is at least two hours. Less than two hours makes it difficult to remove the silicon or the like from the flow regulating tube 25 completely. From the viewpoint of saving thermal energy consumption, the desirable time for which the surface temperature of the flow regulating tube 25 is kept at the above temperature is 3 to 6 hours. The silicon or the like that has sublimed is exhausted to the outside of the regeneration apparatus 10 from the inert gas exhaust port 19 with the flow of the inert gas introduced through the inert gas introducing unit while the flow regulating tube 25 is subjected to the heat treatment and cooled.

After performing the heat treatment, it is preferable to cool the flow regulating tube 25 from the heat treatment temperature to room temperature at a rate of 3 to 15° C./minute. At a rate less than 3° C./minute, a difference in coefficient of thermal expansion between the flow regulating tube 25 and the silicon or the like is not large and the silicon or the like does not fall off the flow regulating tube 25 easily. Moreover, at a rate exceeding 20° C./minute, there is a possibility that a crack appears in the flow regulating tube. After the flow regulating tube 25 is cooled, the flow regulating tube 25 is taken out of the regeneration apparatus 10, whereby a regenerated flow regulating tube from which the silicon or the like has been completely removed is obtained. In order to achieve more enhancement in the quality of the regenerated flow regulating tube, it is preferable to blow air on the surface of the flow regulating tube with a blower or clean the surface of the flow regulating tube with a brush or cloth.

Incidentally, as a member to be regenerated, a thermal shielding member has been taken up as an example in the first embodiment and a flow regulating tube has been taken up as an example in the second embodiment; however, a member that can be regenerated by the method of the present invention is not limited to these members and may be, for example, the support member 22 depicted in FIG. 1, a seed chuck made of graphite, an exhaust pipe made of graphite, or a CC composite material that is used in a part supporting the thermal shielding member. In the case of the CC composite material, it is preferable that, after the CC composite material is subjected to heat treatment and cooled, the surface thereof is vacuumed, by a vacuum clear or the like to remove the silicon or the like remaining between the carbon fibers.

### EXAMPLES

Next, Examples of the present invention will be explained in detail along with Comparative Examples.

### Example 1

A thermal shielding member whose base material was graphite and whose surface was coated with SiC was attached to a particular pulling apparatus and a silicon single crystal was pulled upwardly ten times, whereby silicon or the like was made to adhere to the surface of this thermal shielding member. The average of adhesion thicknesses in ten places where the amount of adhesion was relatively large was 610 μm. The above-described thermal shielding member 21 to which the silicon or the like adheres was attached to the support member 22 of the regeneration apparatus 10 depicted in FIG. 1 and argon gas was introduced from the inert gas introducing unit to set the inside of the chamber 11 in an argon atmosphere. Moreover, the vacuum pump was operated to set the pressure inside the chamber 11 at 1.33 kPa. In this state, the heater 12 was energized until the surface temperature of the thermal shielding member 21 became 1700° C. After the temperature was kept at 1700° C. for 6 hours, the power to the heater 21 was disconnected and the thermal shielding member 21 was cooled to room temperature. The cooling rate was 4.0° C./minute.

### Example 2

The heater was energized until the surface temperature of the thermal shielding member whose average adhesion thickness was 530 μm as a result of a silicon single crystal having been pulled upwardly ten times became 2500° C. After the temperature was kept at 2500° C. for 5 hours, the cooling rate was set at 5.9° C./minute. Heat treatment was performed on the same thermal shielding member coated with SiC as that in Example 1 in a manner similar to Example 1 except for those described above by using the same apparatus as that used in Example 1.

### Example 3

A thermal shielding member made of graphite and coated with a carbon film was attached to a pulling apparatus of the same model as the pulling apparatus used in Example 1 and a silicon single crystal was pulled upwardly ten times, whereby silicon or the like was made to adhere to the surface of this thermal shielding member. The average of adhesion thicknesses in ten places where the amount of adhesion was relatively large was 545 μm. Heat treatment was performed on this thermal shielding member by using the regeneration apparatus 10 depicted in FIG. 1. The heater was energized until the surface temperature of the thermal shielding member became 1750° C. The temperature was kept at 1750° C. for 6 hours. Heat treatment was performed on the thermal shielding member coated with a carbon film in a manner similar to Example 1 except for those described above.

### Example 4

A thermal shielding member which was not coated with SiC nor with a carbon film was attached to a pulling apparatus of the same model as the pulling apparatus used in Example 1 and a silicon single crystal was pulled upwardly ten times, whereby silicon or the like was made to adhere to the surface of this thermal shielding member. The average of adhesion thicknesses in ten places where the amount of adhesion was relatively large was 580 μm. Heat treatment was performed on this thermal shielding member by using the regeneration apparatus 10 depicted in FIG. 1. A temperature at which heat treatment for regeneration was kept was set at 1700° C., the time for which the temperature was kept at that temperature was set at 6 hours, the pressure inside the chamber 11 was set at 2.67 kPa, and the cooling rate after heat treatment was set at 4.0° C./minute. Heat treatment was performed on the thermal shielding member which was not coated with SiC nor with a carbon film in a manner similar to Example 1 except for those described above.

### Example 5

A flow regulating tube formed of a quartz glass material was attached to a pulling apparatus of the same model as the pulling apparatus used in Example 1 and a silicon single crystal was pulled upwardly ten times, whereby silicon or the like was made to adhere to the surface of this flow regulating tube. The average of adhesion thicknesses in ten places where the amount of adhesion was relatively large was 123 μm. Heat treatment was performed on this flow regulating tube by using the regeneration apparatus 10 depicted in FIG. 2. A temperature at which heat treatment for regeneration was kept was set at 1400° C., the time for which the temperature was kept at that temperature was set at 3 hours, the pressure inside the chamber 11 was set at 1.33 kPa, and the cooling rate after heat treatment was set at 3.1° C./minute. Heat treatment was performed on the flow regulating tube formed of a quartz glass material in a manner similar to Example 1 except for those described above.

### Example 6

The heater was energized until the surface temperature of a flow regulating tube whose average adhesion thickness was 135 μm as a result of a silicon single crystal having been pulled upwardly ten times became 1700° C. After the temperature was kept at 1700° C. for 2 hours, the cooling rate was set at 3.8° C./minute. Heat treatment was performed on the same flow regulating tube formed of a quartz glass material as that in Example 5 in a manner similar to Example 1 except for those described above by using the regeneration apparatus 10 depicted in FIG. 2.

### Example 7

A flow regulating tube made of graphite, which was not coated with SiC nor with a carbon film, was attached to a pulling apparatus of the same model as the pulling apparatus used in Example 1 and a silicon single crystal was pulled upwardly ten times, whereby silicon or the like was made to adhere to the surface of this flow regulating tube. The average of adhesion thicknesses in ten places where the amount of adhesion was relatively large was 141 μm. Heat treatment was performed on this flow regulating tube by using the regeneration apparatus 10 depicted in FIG. 2. A temperature at which heat treatment for regeneration was kept was set at 1700° C., the time for which the temperature was kept at that temperature was set at 4 hours, the pressure inside the chamber 11 was set at 1.33 kPa, and the cooling rate after heat treatment was set at 3.8° C./minute. Heat treatment was performed on the flow regulating tube made of graphite, which was not coated with SiC nor with a carbon film, in a manner similar to Example 1 except for those described above.

### Comparative Example 1

The same thermal shielding member made of graphite as that in Example 1, the thermal shielding member whose surface was coated with SiC, was attached to a pulling apparatus of the same model as the pulling apparatus used in Example 1 and a silicon single crystal was pulled upwardly ten times, whereby silicon or the like was made to adhere to the surface of this thermal shielding member. The average of adhesion thicknesses in ten places where the amount of adhesion was relatively large was 527 μm. Heat treatment was performed on this thermal shielding member by using the regeneration apparatus 10 depicted in FIG. 1. A temperature at which heat treatment for regeneration was kept was set at 1650° C., the time for which the temperature was kept at that temperature was set at 4 hours, the pressure inside the chamber 11 was set at 1.33 kPa, and the cooling rate after heat treatment was set at 3.7° C./minute. Heat treatment was performed on the thermal shielding member coated with SiC in a manner similar to Example 1 except for those described above.

### Comparative Example 2

The same thermal shielding member made of graphite as that in Example 1, the thermal shielding member whose surface was coated with SiC, was attached to a pulling apparatus of the same model as the pulling apparatus used in Example 1 and a silicon single crystal was pulled upwardly ten times, whereby silicon or the like was made to adhere to the surface of this thermal shielding member. The average of adhesion thicknesses in ten places where the amount of adhesion was relatively large was 582 μm. Heat treatment was performed on this thermal shielding member by using the regeneration apparatus 10 depicted in FIG. 1. A temperature at which heat treatment for regeneration was kept was set at 2550° C., the time for which the temperature was kept at that temperature was set at 5 hours, the pressure inside the chamber 11 was set at 1.33 kPa, and the cooling rate after heat treatment was set at 6.0° C./minute. Heat treatment was performed on the thermal shielding member coated with SiC in a manner similar to Example 1 except for those described above.

### Comparative Example 3

The same thermal shielding member made of graphite as that in Example 1, the thermal shielding member whose surface was coated with SiC, was attached to a pulling apparatus of the same model as the pulling apparatus used in Example 1 and a silicon single crystal was pulled upwardly ten times, whereby silicon or the like was made to adhere to the surface of this thermal shielding member. The average of adhesion thicknesses in ten places where the amount of adhesion was relatively large was 560 μm. Heat treatment was performed on this thermal shielding member by using the regeneration apparatus 10 depicted in FIG. 1. A temperature at which heat treatment for regeneration was kept was set at 1750° C. and the time for which the temperature was kept at that temperature was set at 1.8 hours. Heat treatment was performed on the thermal shielding member coated with SiC in a manner similar to Example 1 except for those described above.

### Comparative Example 4

The same thermal shielding member as that in Example 4, which was not coated with SiC nor with a carbon film, was attached to a pulling apparatus of the same model as the pulling apparatus used in Example 1 and a silicon single crystal was pulled upwardly ten times, whereby silicon or the like was made to adhere to the surface of this thermal shielding member. The average of adhesion thicknesses in ten places where the amount of adhesion was relatively large was 509 μm. Heat treatment was performed on this thermal shielding member by using the regeneration apparatus 10 depicted in FIG. 1. A temperature at which heat treatment for regeneration was kept was set at 1650° C., the time for which the temperature was kept at that temperature was set at 6 hours, and the pressure inside the chamber. 11 was set at 4.0 kPa. Heat treatment was performed on the thermal shielding member which was not coated with SiC nor with a carbon film in a manner similar to Example 1 except for those described above.

### Comparative Example 5

The same flow regulating tube formed of a quartz glass material as that in Example 5 was attached to a pulling apparatus of the same model as the pulling apparatus used in Example 1 and a silicon single crystal was pulled upwardly ten times, whereby silicon or the like was made to adhere to the surface of this flow regulating tube. The average of adhesion thicknesses in ten places where the amount of adhesion was relatively large was 115 μm. Heat treatment was performed on this flow regulating tube by using the regeneration apparatus 10 depicted in FIG. 2. A temperature at which heat treatment for regeneration was kept was set at 1350° C., the time for which the temperature was kept at that temperature was set at 2 hours, the pressure inside the chamber 11 was set at 1.33 kPa, and the cooling rate after heat treatment was set at 2.9° C./minute. Heat treatment was performed on the flow regulating tube formed of a quartz glass material in a manner similar to Example 1 except for those described above.

### Comparative Example 6

The heater was energized until the surface temperature of a flow regulating tube whose average adhesion thickness was 129 μm as a result of a silicon single crystal having been pulled upwardly ten times became 1750° C. Heat treatment was performed with the temperature kept at 1750° C. for 0.3 hours. Heat treatment was performed on the same flow regulating tube formed of a quartz glass material as that in Example 5 in a manner similar to Example 1 except for those described above by using the same apparatus as that used in Example 1.

### Comparative Example 7

The same thermal shielding member made of graphite as that in Example 1, the thermal shielding member whose surface was coated with SiC, was attached to a pulling apparatus of the same model as the pulling apparatus used in Example 1 and a silicon single crystal was pulled upwardly ten times, whereby silicon or the like was made to adhere to the surface of this thermal shielding member. The average of adhesion thicknesses in ten places where the amount of adhesion was relatively large was 532 μm. This thermal shielding member was regenerated by an etching processing method in accordance with the method described in Patent Document 1. First, a mixed acid of hydrofluoric acid and nitric acid, which was a chemical solution, was stored in a chemical solution, the thermal shielding member to which the silicon or the like adheres was then immersed in the chemical solution, and ultrasonic cleaning was performed thereon. The thermal shielding member from which the silicon or the like had been removed by cleaning was transferred from the chemical solution to a rinse in which pure water was stored and immersed in the pure water. After ultrasonic cleaning was performed on the thermal shielding member in this rinse as in the chemical solution, the thermal shielding member was pulled upwardly from the rinse and dried, whereby regeneration was completed.

### Comparative Example 8

The same thermal shielding member made of graphite as that in Example 1, the thermal shielding member whose surface was coated with SiC, was attached to a pulling apparatus of the same model as the pulling apparatus used in Example 1 and a silicon single crystal was pulled upwardly ten times, whereby silicon or the like was made to adhere to the surface of this thermal shielding member. The average of adhesion thicknesses in ten places where the amount of adhesion was relatively large was 590 μm. The surface of this thermal shielding member was ground by using a grinding wheel (grain size #1000) described in Patent Document 2, whereby the silicon or the like adhering to the surface of the thermal shielding member was mechanically removed.

<Comparative Test I and Evaluation>

The thermal shielding members or flow regulating tubes used in Examples 1 to 7 and Comparative Examples 1 to 8 were examined to determine adhesion of silicon or the like after regeneration, a change in the member wall thickness before and after regeneration, the presence or absence of degradation or a flaw in the member surface after regeneration, and the time required for regeneration. The wall thickness of a member was measured with a vernier caliper in ten places, and the average value of the wall thicknesses after regeneration was expressed as a ratio (average rate of change in wall thickness) on the assumption that the value before regeneration is 1. Adhesion of silicon or the like and the presence or absence of degradation or a flaw in the member surface after regeneration were judged by a visual inspection. The results are shown in Table 1.

TABLE 1

| | | | Heat treatment conditions | | | |
|---|---|---|---|---|---|---|
| | | | | Surface | | |
| | | | Pressure | tem- | Keeping | |
| | | | inside | perature | time of | Cooling |
| | | | the | of the | heat | rate |
| | Member | | chamber | member | treatment | (° C./ |
| | Type | Material | (kPa) | (° C.) | (hr) | min) |
| Ex. 1 | Thermal | Graphite | 1.33 | 1700 | 6 | 4.0 |
| | shielding | coated | | | | |
| | member | with SiC | | | | |
| Ex. 2 | Thermal | Graphite | 1.33 | 2500 | 5 | 5.9 |
| | shielding | coated | | | | |
| | member | with SiC | | | | |
| Ex. 3 | Thermal | Graphite | 1.33 | 1750 | 6 | 4.0 |
| | shielding | coated | | | | |
| | member | with | | | | |
| | | carbon | | | | |
| | | film | | | | |
| Ex. 4 | Thermal | Graphite | 2.67 | 1700 | 6 | 4.0 |
| | shielding | without | | | | |
| | member | coating | | | | |
| Ex. 5 | Flow | Quartz | 1.33 | 1400 | 3 | 3.1 |
| | regulating | glass | | | | |
| | tube | | | | | |
| Ex. 6 | Flow | Quartz | 1.33 | 1700 | 2 | |
| | regulating | glass | | | | |
| | tube | | | | | |
| Ex. 7 | Flow | Graphite | 1.33 | 1700 | 4 | 3.8 |
| | regulating | without | | | | |
| | tube | coating | | | | |
| Com. | Thermal | Graphite | 1.33 | 1650 | 4 | 3.7 |
| Ex. 1 | shielding | coated | | | | |
| | member | with SiC | | | | |
| Com. | Thermal | Graphite | 1.33 | 2550 | 5 | 6.0 |
| Ex. 2 | shielding | coated | | | | |
| | member | with SiC | | | | |
| Com. | Thermal | Graphite | 1.33 | 1750 | 1.8 | 4.0 |
| Ex. 3 | shielding | coated | | | | |
| | member | with SiC | | | | |
| Com. | Thermal | Graphite | 4.0 | 1650 | 6 | 4.0 |
| Ex. 4 | shielding | without | | | | |
| | member | coating | | | | |
| Com. | Flow | Quartz | 1.33 | 1350 | 2 | 2.9 |
| Ex. 5 | regulating | glass | | | | |
| | tube | | | | | |
| Com. | Flow | Quartz | 1.33 | 1750 | 3 | 4.0 |
| Ex. 6 | regulating | glass | | | | |
| | tube | | | | | |
| Com. | Thermal | Graphite | — | — | — | — |
| Ex. 7 | shielding | coated | | | | |
| | member | with SiC | | | | |
| Com. | Thermal | Graphite | — | — | — | — |
| Ex. 8 | shielding | coated | | | | |
| | member | with SiC | | | | |

| | | | Average | presence or | |
|---|---|---|---|---|---|
| | | | rate of | absence of | |
| | | | change in | degradation | |
| | Adhering | | wall | or a | |
| | average | Adhesion | thickness | flaw in the | Time |
| | thickness | of Si or | of the | member | required |
| | of Si or | the like | member | surface | for re- |
| | the like | after | after | after | generation |
| | (μm) | regeneration | regeneration | regeneration | (hr) |
| Ex. 1 | 610 | None | 1 | None | 13.5 |
| Ex. 2 | 530 | None | 1 | None | 12.5 |
| Ex. 3 | 545 | None | 1 | None | 13.5 |
| Ex. 4 | 580 | None | 1 | None | 13.5 |
| Ex. 5 | 123 | None | 1 | None | 10.5 |
| Ex. 6 | 135 | None | 1 | None | 9.5 |
| Ex. 7 | 141 | None | 1 | None | 11.5 |
| Com. | 527 | Adhesion | 1 | None | 11.5 |
| Ex. 1 | | remained | | | |
| Com. | 582 | None | 1 | Coating | 12.5 |
| Ex. 2 | | | | peeled off | |
| Com. | 560 | Adhesion | 1 | None | 9.3 |
| Ex. 3 | | remained | | | |
| Com. | 509 | Adhesion | 1 | None | 13.5 |
| Ex. 4 | | remained | | | |
| Com. | 115 | Adhesion | 1 | None | 9.5 |
| Ex. 5 | | remained | | | |
| Com. | 129 | None | 0.96 | None | 10.5 |
| Ex. 6 | | | | | |
| Com. | 532 | Adhesion | 1 | None | 326 |
| Ex. 7 | | remained | | | |
| Com. | 590 | Adhesion | 1 | Many flaws | 12.0 |
| Ex. 8 | | remained | | | |

As is clear from Table 1, in the thermal shielding member made of graphite and coated with SiC of Comparative Example 1 on which heat treatment was performed at 1650° C., silicon or the like adhered thereto after regeneration processing. Moreover, in the thermal shielding member made of graphite and coated with SiC of Comparative Example 2 on which heat treatment was performed at 2550° C., the SiC coating on the surface of the thermal shielding member peeled off after regeneration processing. Furthermore, in the thermal shielding member made of graphite and coated with SiC of Comparative Example 3 on which heat treatment was performed at 1750° C. at a pressure of 1.33 kPa for 1.8 hours, silicon or the like adhered thereto after regeneration processing. In addition, in the thermal shielding member which was made of graphite and not coated with SiC nor with a carbon film of Comparative Example 4 on which heat treatment was performed at 1650° C. at a pressure of 4.0 kPa, silicon or the like adheres thereto after regeneration processing. Moreover, in the flow regulating tube formed of a quartz glass material of Comparative Example 5 on which heat treatment was performed at 1350° C., silicon or the like adhered thereto after regeneration processing. Furthermore, in the flow regulating tube formed of a quartz glass material of Comparative Example 6 on which heat treatment was performed at 1750° C., the flow regulating tube became thermally deformed after heat treatment processing and the average rate of change in wall thickness was 0.96. Moreover, in the thermal shielding member which was made of graphite, coated with SiC, and regenerated by the etching processing method using chemical cleaning of Comparative Example 7, it took 326 hours to complete regeneration. Furthermore, in the thermal shielding member which was made of graphite and coated with SiC of Comparative Example 8, the thermal shielding member whose surface was ground with a grinding wheel to mechanically remove the silicon or the like adhered thereto, the silicon or the like adhered thereto after regeneration processing and many flaw caused by grinding were present in the surface.

By contrast, no silicon or the like adhered to the thermal shielding members and the flow regulating tubes regenerated in Examples 1 to 7, the average rate of change in wall thickness of each of these members was 1, meaning that no change in wall thickness and thermal deformation had occurred, and the coating did not peel off and there was no flaw in the surface of the member. In addition thereto, the time required for regeneration was relatively short, ranging from 9.5 to 13.5 hours, meaning that it was possible to perform regeneration quickly.

<Comparative Test II and Evaluation>

Two silicon single crystal pulling apparatuses of the same model were selected, two thermal shielding members whose base materials were made of graphite and whose surfaces were coated with SiC, the thermal shielding members selected from the same production lot, were separately attached to the two pulling apparatuses, the same silicon raw material was put into the crucibles, and, after the silicon raw material was turned into silicon melt, a silicon single crystal was pulled upwardly by the two apparatuses under the same pulling conditions. The crucible of one of the two pulling apparatuses was changed with that of the other, and, after a silicon single crystal was repeatedly pulled upwardly ten times by each apparatus under the same pulling conditions, silicon or the like adhered to the surfaces of the two thermal shielding members. One thermal shielding member was regenerated by the method of Example 1, and the other thermal shielding member was regenerated by the method of Comparative Example 7. After regeneration, the two thermal shielding members were attached to the same pulling apparatus again and silicon or the like was made to adhere to the surfaces of the two thermal shielding members in a similar manner. Regeneration of the two thermal shielding members and adhesion of silicon or the like thereto were repeatedly performed, and the numbers of times of the above operation performed until the SiC coatings of the two thermal shielding members peeled off were measured. As a result, in the method of Comparative Example 7, the SiC coating began to peel off when the above operation was performed 70 times; by contrast, in the method of Example 1, the SiC coating began to peel off when the above operation was performed 220 times. As a result, the thermal shielding member regenerated in accordance with Example 1 could be used more than three times longer than the thermal shielding member regenerated in accordance with Comparative Example 7 and the length of life of the thermal shielding member could be greatly extended.

<Comparative Test III and Evaluation>

Three silicon single crystal pulling apparatuses of the same model were selected, three thermal shielding members whose base materials were made of graphite and whose surfaces were coated with SiC, the thermal shielding members selected from the same production lot, were separately attached to the three pulling apparatuses, the same silicon raw material was put into the crucibles, and, after the silicon raw material was turned into silicon melt, a silicon single crystal was pulled upwardly by the three apparatuses under the same pulling conditions. After a silicon single crystal was repeatedly pulled upwardly ten times by each apparatus under the same pulling conditions, silicon or the like adhered to the surfaces of the three thermal shielding members. One thermal shielding member was regenerated by the method of Example 1. One of the other thermal shielding members was regenerated by the method of Comparative Example 1. The remaining one thermal shielding member was not regenerated. These three thermal shielding members were attached to the same pulling apparatus and another ten silicon single crystals were then pulled upwardly under the same pulling conditions. The single crystallization degrees (Dislocation Free Ratio) of the ten silicon single crystals pulled upwardly by each of the three pulling apparatuses were measured. As a result, if the single crystallization degrees of the silicon single crystals pulled upwardly by using the thermal shielding member which was not regenerated were assumed to be 100, the single crystallization degrees of the silicon single crystals pulled upwardly by using the thermal shielding member which was regenerated by the method of Comparative Example 1 were 100.4; by contrast, the single crystallization degrees of the silicon single crystals pulled upwardly by using the thermal shielding member regenerated by the method of Example 1 averaged 102.2, which revealed that the single crystallization degree improved by about 2%. An improvement in the single crystallization degree was thought to be due to a smaller quantity of the silicon or the like that fell into the silicon melt from the thermal shielding member and mixed thereinto than the other two examples.

<Comparative Test IV and Evaluation>

295 silicon single crystals, each being of p-type with a diameter of 200 mm and crystal orientation <100>, were pulled upwardly by a pulling apparatus having a thermal shielding member regenerated by the etching processing method of Comparative Example 6. The resistivity of each of silicon wafers cut out of these single crystals was measured by a four-terminal method. The lifetime of a silicon wafer whose resistivity was 5 Ω·cm or more was converted into 10 Ω·cm, and each lifetime′ was determined as a relative value on the assumption that the average value of these lifetimes was 1. On the other hand, ten silicon single crystals, each being of p-type with a diameter of 200 mm and crystal orientation <100>, were pulled upwardly by the same pulling method by using the same raw material by the same pulling apparatus except for a thermal shielding member regenerated by the method of Example 1. The resistivity of each of silicon wafers cut out of these single crystals was measured by the same method as that described above and the resistivity thus obtained was converted into 10 Ω·cm in a manner similar to that described above. A comparison of each of the relative values of the lifetimes obtained by conversion with the average value of the lifetimes of the resistivity of Comparative Example 7 revealed that the lifetimes of the silicon wafers produced by the pulling apparatus having the thermal shielding member regenerated by the method of Example 1 improved by an average of about 18% as compared to the lifetimes of the silicon wafers produced by the pulling apparatus having the thermal shielding member regenerated by the method of Comparative Example 7 and exhibited reduced variations. As a result, it was confirmed that the cleaning level of the regeneration processing performed on the thermal shielding member by the method of Example 1 was higher than the cleaning level of the regeneration processing performed on the thermal shielding member by the method of Comparative Example 7.

### INDUSTRIAL APPLICABILITY

The regeneration method of the present invention is used to regenerate a member, to which silicon or the like adheres, in a silicon single crystal pulling apparatus by removing the silicon or the like therefrom by subliming the silicon or the like.

1. A method for regenerating a member in a silicon single crystal pulling apparatus, the method that regenerates a member which is provided in a silicon single crystal pulling apparatus by removing any one of SiOx and silicon metal or both adhering to a surface of the member, wherein
the one of SiOx and silicon metal or both adhering to the surface of the member is removed by subliming the one of SiOx and silicon metal or both by performing heat treatment, for at least two hours, on the member with the surface to which the one of SiOx and silicon metal or both adheres in an inert gas atmosphere at a pressure of 2.67 kPa or less at a temperature, at which a surface temperature of the member is higher than or equal to a temperature at which sublimation of the one of SiOx and silicon metal or both adhering to the surface starts, which is lower than a temperature at which the member starts any one of thermal deformation and thermal alteration or both.

2. The regeneration method according to claim 1, wherein
after the heat treatment is performed, the member is cooled from the heat treatment temperature to room temperature at a rate of 3 to 15° C./minute.

3. The regeneration method according to claim 1, wherein
the member is a graphite member and the heat treatment temperature is at least 1700° C. or more.

4. The regeneration method according to claim 3, wherein
the graphite member is a graphite member coated with SiC and the heat treatment temperature is 1700° C. or higher but 2500° C. or lower.

5. The regeneration method according to claim 3, wherein
the graphite member is a graphite member coated with a carbon film and the heat treatment temperature is 1700° C. or higher but 2500° C. or lower.

6. The regeneration method according to claim 3, wherein
the graphite member is a thermal shielding member.

7. The regeneration method according to claim 1, wherein
the member is a quartz member and the heat treatment temperature is 1400° C. or higher but 1700° C. or lower.

8. The regeneration method according to claim 7, wherein
the quartz member is a flow regulating tube.

9. A member that is provided in a silicon single crystal pulling apparatus, the member regenerated by the method according to claim 1.

10. A method for producing a silicon single crystal by using a member regenerated by the method according to claim 1.
